(19) United States
(12) Patent Application Publication
(10) Pub. No.: US 2008/0156509 A1
(43) Pub. Date: Jul. 3, 2008

(54) ELECTRONIC EQUIPMENT ENCLOSURE AND ELECTRONIC EQUIPMENT HAVING THE ENCLOSURE

(75) Inventor: Shunsuke Ikeo, Tokyo (JP)

Correspondence Address: BELL, BOYD & LLOYD, LLP, P. O. BOX 1135, CHICAGO, IL, 60690, US

(73) Assignee: SONY CORPORATION, Tokyo (JP)

(21) Appl. No.: 11/946,576

(22) Filed: Nov. 28, 2007

(30) Foreign Application Priority Data
Dec. 27, 2006 (JP) 2006-352607

(51) Int. Cl. H05K 5/00

(52) U.S. Cl. 174/50

(57) ABSTRACT

Electronic equipment enclosure and electronic equipment having the enclosure are provided: the enclosure covers at least part of an electronic equipment main body. The enclosure includes a flat metal plate layer die cast on an inner surface; and a flat resin plate layer molded on an outer surface to almost entirely cover an outer surface of the metal plate layer. Further, the enclosure includes a two-layer structure of the metal plate layer and the resin plate layer.

### CROSS REFERENCES TO RELATED APPLICATIONS

The present application claims priority to Japanese Patent Application JP 2006-352607 filed in the Japanese Patent Office on Dec. 27, 2006, the entire contents of which is being incorporated herein by reference.

### BACKGROUND

The present application relates to an enclosure used for electronic equipment such as an imaging device or audio equipment, and electronic equipment having the enclosure. More particularly, the present application relates to an enclosure including a flat metal plate layer on an inner surface and a flat resin plate layer on an outer surface, the enclosure formed to have a two-layer structure of the metal plate layer and the resin plate layer, and electronic equipment having the enclosure.

Japanese Unexamined Patent Application Publication No. 8-236951 discloses an example of an electronic equipment enclosure of the related art. The Publication discloses electronic equipment including an electronic circuit and various mechanisms enclosed in an external enclosure. The electronic equipment disclosed in the Publication (hereinafter referred to as “first related art example”) includes a main chassis formed by magnesium die casting, the main chassis forming at least part of an outer shell of an external enclosure and holding a member enclosed in the external enclosure.

The electronic equipment having such a configuration may be provided with an external enclosure having sufficient strength and stiffness but reduced in weight, the external enclosure having a simplified configuration and easily assembled and manufactured (paragraph [0066] of the specification).

Japanese Unexamined Patent Application Publication No. 2005-63534 discloses another example of electronic equipment of the related art. The Publication discloses a disc recording and/or reproduction device suitably used for an imaging device with a disc-shaped recording medium as an information storage medium, and having a heat source in an exterior case. The disc recording and/or reproduction device disclosed in Japanese Unexamined Patent Application Publication No. 2005-63534 (hereinafter referred to as “second related art example”) includes a table rotating device to rotationally drive a detachably attached disc-shaped recording medium; a pickup device to record and/or reproduce information signals in the disc-shaped recording medium rotationally driven by the table rotating device; a printed circuit board having a control circuit mounted to control driving of the table rotating device and the pickup device; and an exterior case to enclose the table rotating device, the pickup device, and the printed circuit board, where the exterior case has a fluid passage with one or both edges opening and has a fan in the fluid passage.

In the disc recording and/or reproduction device having such a configuration, heat in the exterior case may be discharged from the fluid passage to outside by causing cooling air to flow into the exterior case from outside the exterior case through the fluid passage. This allows heat generated in the heat source in the exterior case to be radiated to outside to prevent or suppress the table rotating device or the pickup device from being heated to a high temperature by thermal influence, making it possible to prevent or suppress a malfunction or reduced rotation efficiency of the table rotating device or the like due to an unnecessary high temperature of the device (paragraph [0020] of the specification).

In the first related art example, since the main chassis forming part of the external enclosure is formed by magnet die casting, the external enclosure may have sufficient strength and maintain stiffness though the enclosure is thin; however, a magnet die cast surface is generally rough and has inferior appearance. Therefore, when the external enclosure is formed by magnet die casting, a surface of the external enclosure is polished by grinding or the like or coated by applying paint to improve appearance. As a result, when the enclosure is formed by die casting, the enclosure may have a reduced thickness, but surface treatment involves much labor and less cost effective. Further, reinforcement such as a rib may be necessary for reducing a thickness even in magnet die casting; however, a sink (a recess formed on a casting surface) may be formed on the surface by providing the reinforcement rib or the like. Accordingly, even the external enclosure directly formed by magnet die casting may be necessary to have a predetermined thickness or more.

On the other hand, in the second related art example, the exterior case is formed of plastic providing a clear surface per se, and therefore may not have to be surface treated after forming and has excellent appearance. However, since plastic generally has low hardness, the exterior case formed of plastic may be necessary to have an increased thickness to enhance strength. Further, plastic has relatively inferior thermal conductivity to complicate a heat radiation structure to radiate heat from the high-temperature heat source to outside. Thus, a cost may be reduced by the external enclosure formed of plastic, because the plastic surface is clear and does not have to be treated; however, the external enclosure may be necessary to have an increased thickness due to low hardness. As a result, it may be difficult to reduce the thickness and size of the whole device.

### SUMMARY

An enclosure formed of a metal by die casting may have a reduced thickness but may be necessary to be surface treated and this treatment involves much labor and cost. On the other hand, an enclosure formed of plastic may have improved appearance, but does not have sufficient strength and therefore may be necessary to have an increased thickness; this prevents the whole device from being reduced in thickness and size.

According to an embodiment, there is provided an enclosure to cover at least part of an electronic equipment main body, the enclosure including a flat metal plate layer die cast on an inner surface; and a flat resin plate layer molded on an outer surface to almost entirely cover an outer surface of the metal plate layer, the enclosure formed to have a two-layer structure of the metal plate layer and the resin plate layer.

According to an embodiment, there is provided electronic equipment having an electronic equipment main body at least partially covered with an enclosure, the enclosure including a flat metal plate layer die cast on an inner surface; and a flat resin plate layer molded on an outer surface to almost entirely cover an outer surface of the metal plate layer, the enclosure formed to have a two-layer structure of the metal plate layer and the resin plate layer.

In an electronic equipment enclosure or electronic equipment having the enclosure according to an embodiment configured in this manner, the enclosure has a resin plate layer on an outer surface and a metal plate layer on an inner surface and is integrally formed as a two-layer structure of the resin plate layer and the metal plate layer. The enclosure has stiffness of the metal plate layer and appearance of the resin plate layer. Therefore, both the resin plate layer and the metal plate layer may be reduced in thickness, and an enclosure may be provided with strength to a certain extent although the enclosure is thin. Accordingly, an enclosure may be manufactured more inexpensively than in the case where an appearance is formed by die casting, and may be obtained with excellent appearance. Moreover, a high temperature part of the metal plate layer heated to a high temperature is covered with the resin plate layer, so that the high temperature part may not be touched by hands to improve safety and heat radiation efficiency may be improved.

Additional features and advantages are described herein, and will be apparent from, the following Detailed Description and the figures.

### BRIEF DESCRIPTION OF THE FIGURES

FIG. 1 is a front perspective view of a digital camcorder showing a first example of electronic equipment having an enclosure according to an embodiment.

FIG. 2 is a rear perspective view of a digital camcorder with a display device opened, showing a first example of electronic equipment having an enclosure according to an embodiment.

FIG. 3 is a side view of a digital camcorder with a display device opened, showing a first example of electronic equipment having an enclosure according to an embodiment.

FIG. 4 is an external view illustrating a first example of an electronic equipment enclosure according to an embodiment.

FIG. 5 is an external perspective view showing a first example of an electronic equipment enclosure according to an embodiment.

FIG. 6 is an internal perspective view showing a first example of an electronic equipment enclosure according to an embodiment.

FIG. 7 is a perspective view illustrating a state before combining a resin plate layer and a metal plate layer, showing a first example of an electronic equipment enclosure according to an embodiment.

FIG. 8 is an internal perspective view of a resin plate layer, showing a first example of an electronic equipment enclosure according to an embodiment.

FIG. 9 is an internal perspective view of a metal plate layer, showing a first example of an electronic equipment enclosure according to an embodiment.

FIG. 10 shows a formed button part in a first example of an electronic equipment enclosure according to an embodiment, where FIG. 10A is a front perspective view and FIG. 10B is a rear perspective view.

FIG. 11 is an X-X line cross-sectional view of FIG. 3.

FIG. 12 is a Y-Y line cross-sectional view of FIG. 4.

FIG. 13 is a Z-Z line cross-sectional view of FIG. 4.

FIG. 14 is a view describing a relation between a first example of an electronic equipment enclosure according to an embodiment and an electronic equipment main body.

FIG. 15 describes a relation between a metal plate layer of an electronic equipment enclosure according to an embodiment and an electronic equipment main body, where FIG. 15A is a side view and FIG. 15B is a view describing thermal distribution in FIG. 15A.

FIG. 16 describes a relation between a metal plate layer of an electronic equipment enclosure according to an embodiment and an electronic equipment main body, where FIG. 16A is a bottom view and FIG. 16B is a view describing thermal distribution in FIG. 16A.

### DETAILED DESCRIPTION

An enclosure is integrally formed by a two-layer structure of a resin plate layer and a metal plate layer, and has stiffness of the metal plate layer and appearance of the resin plate layer. Accordingly, an electronic equipment enclosure and electronic equipment having the enclosure are simply configured, where the enclosure may have excellent appearance ensured and strength improved and may be inexpensively manufactured.

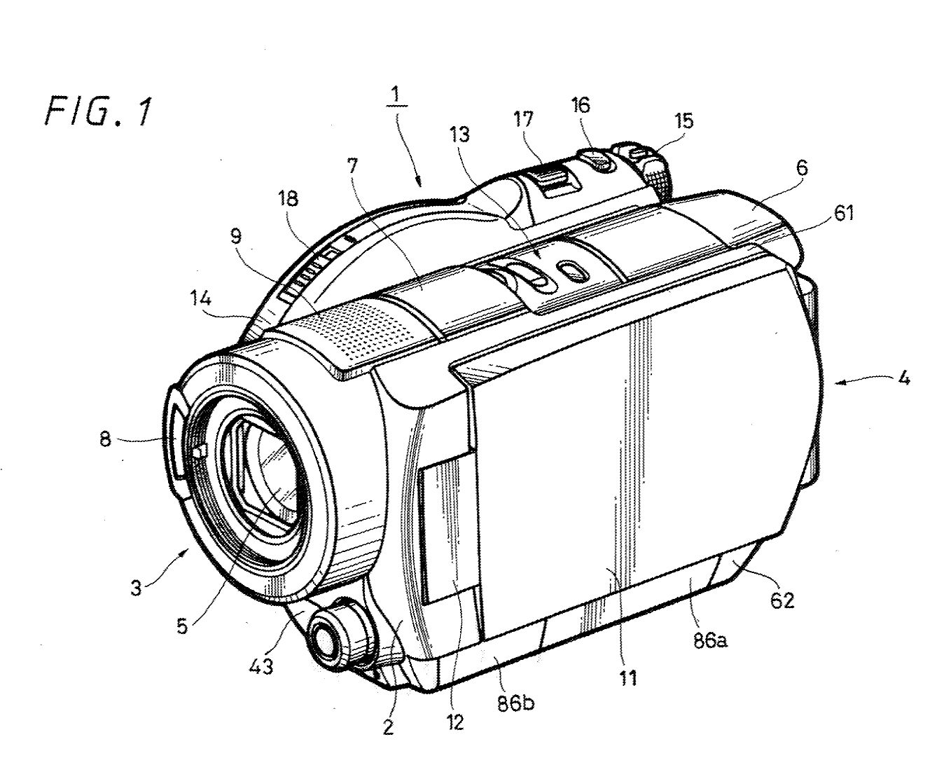

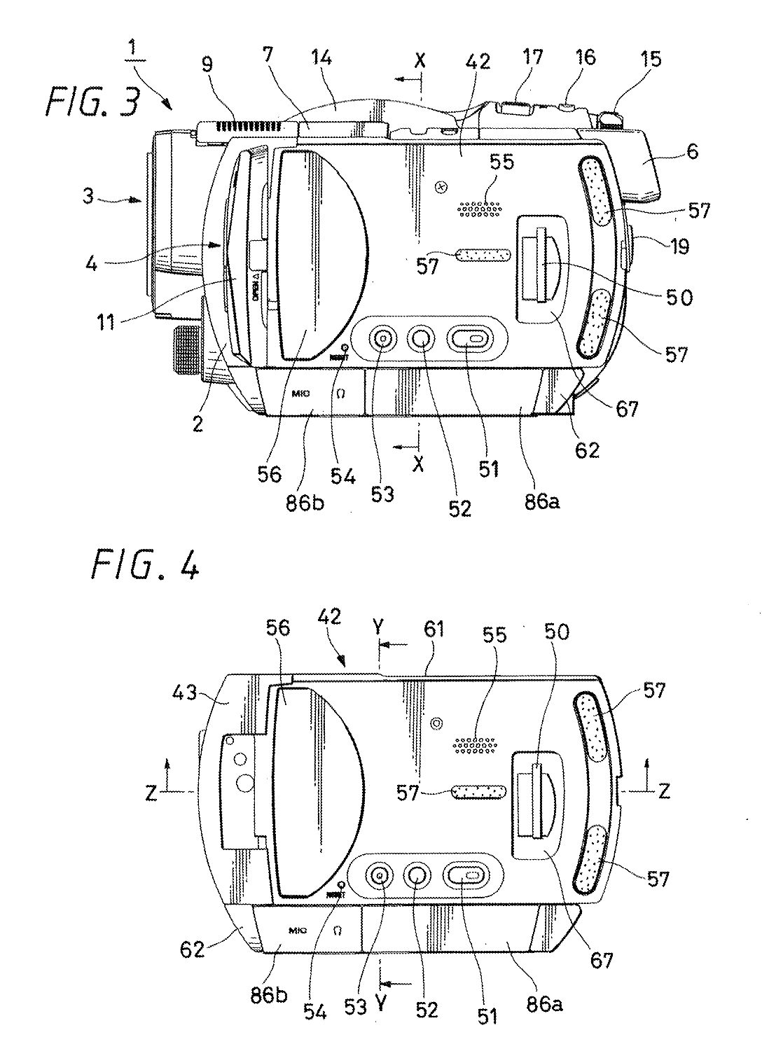

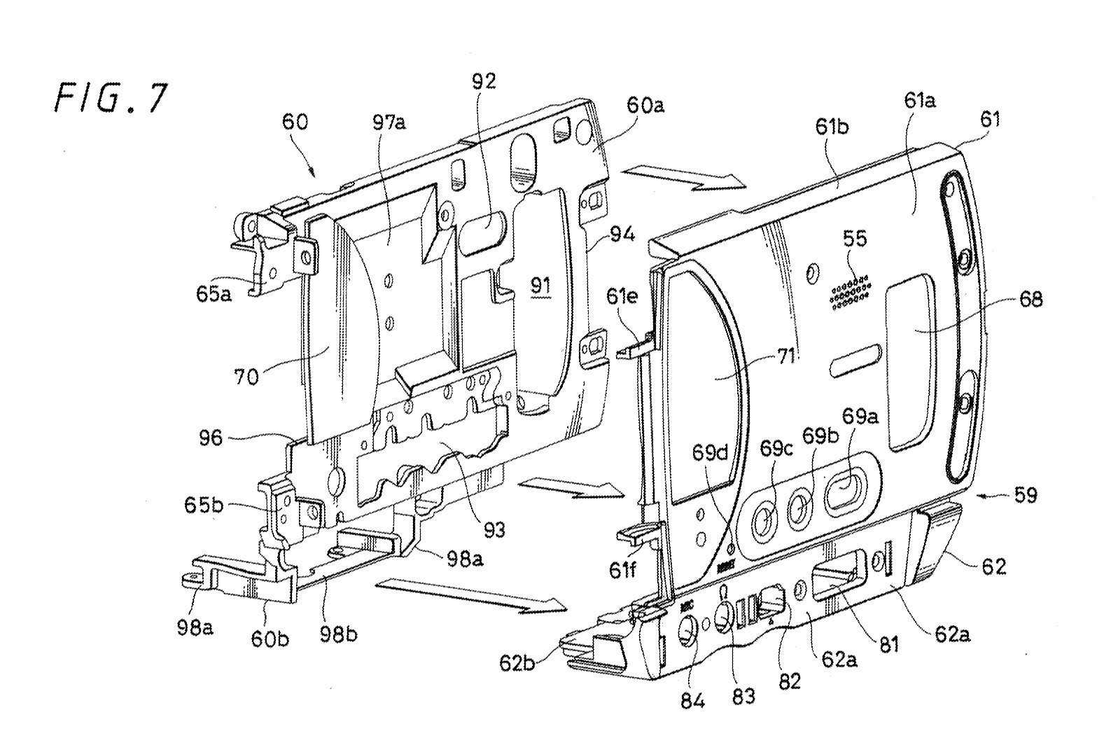

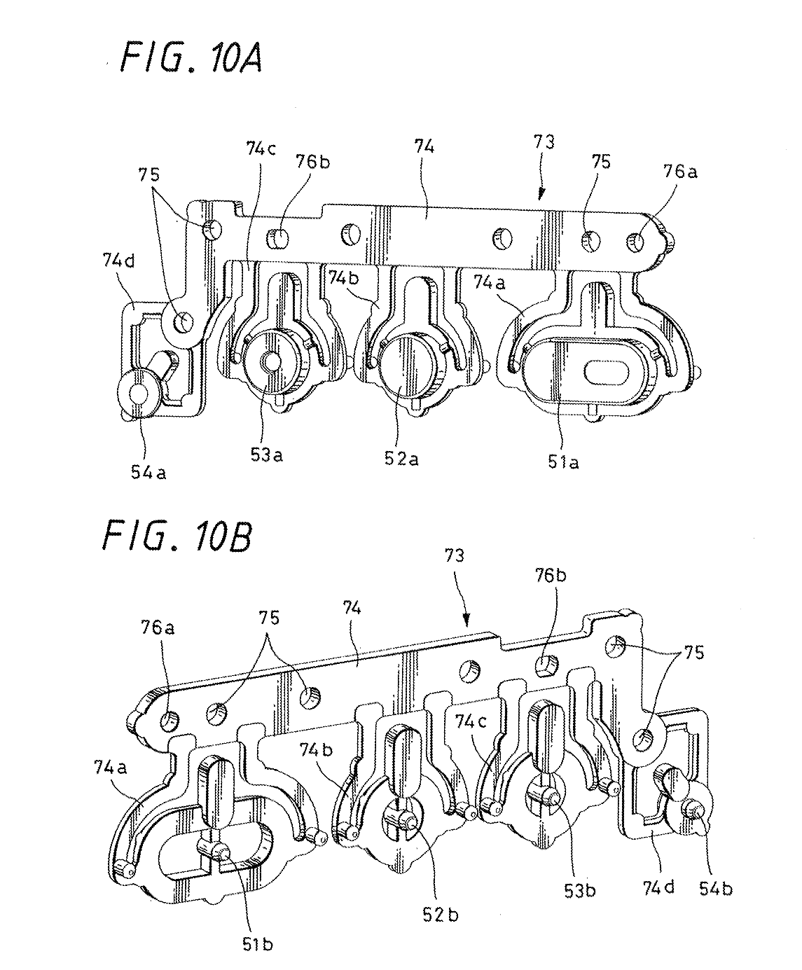

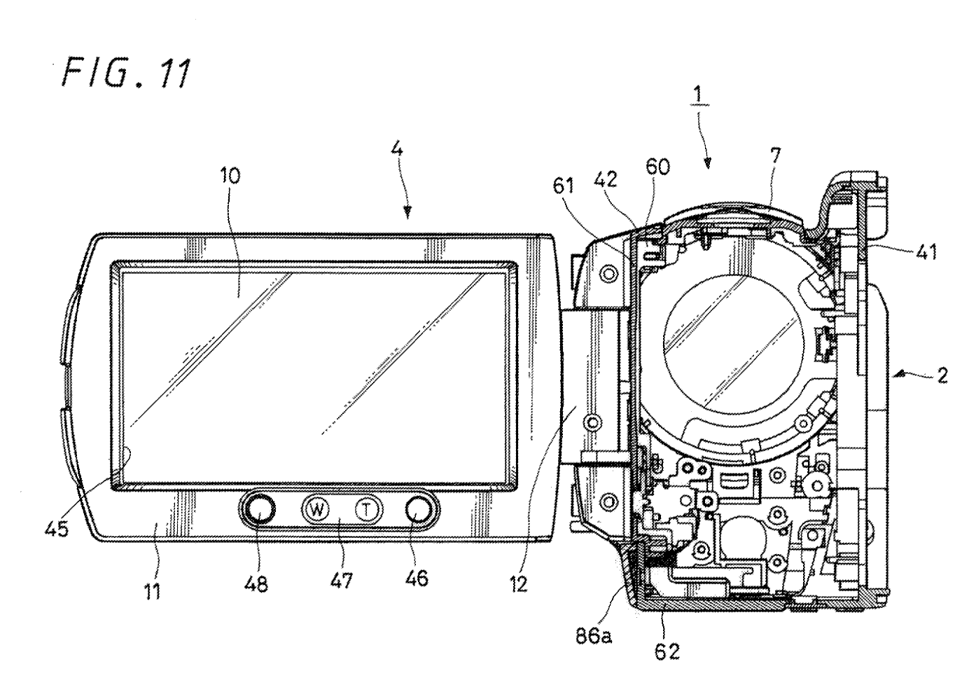

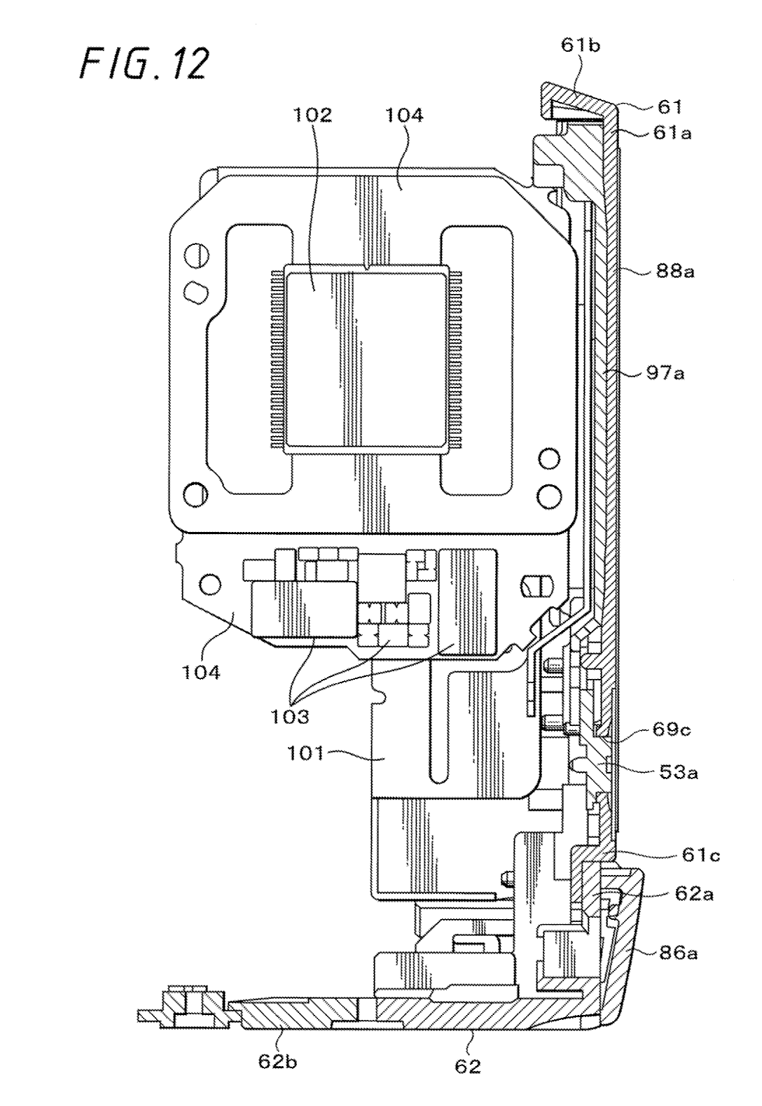

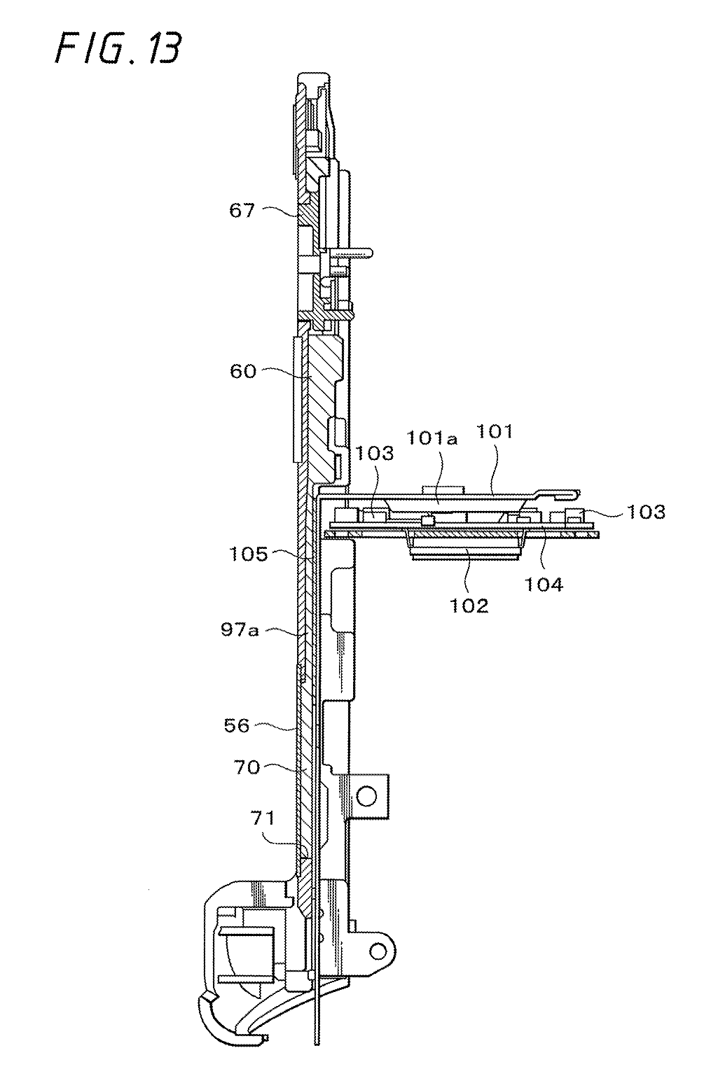

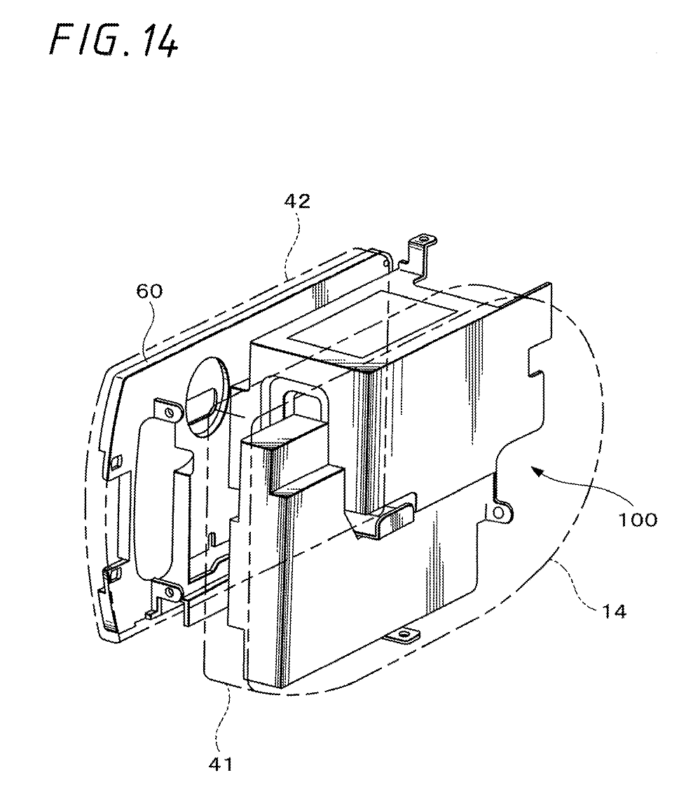

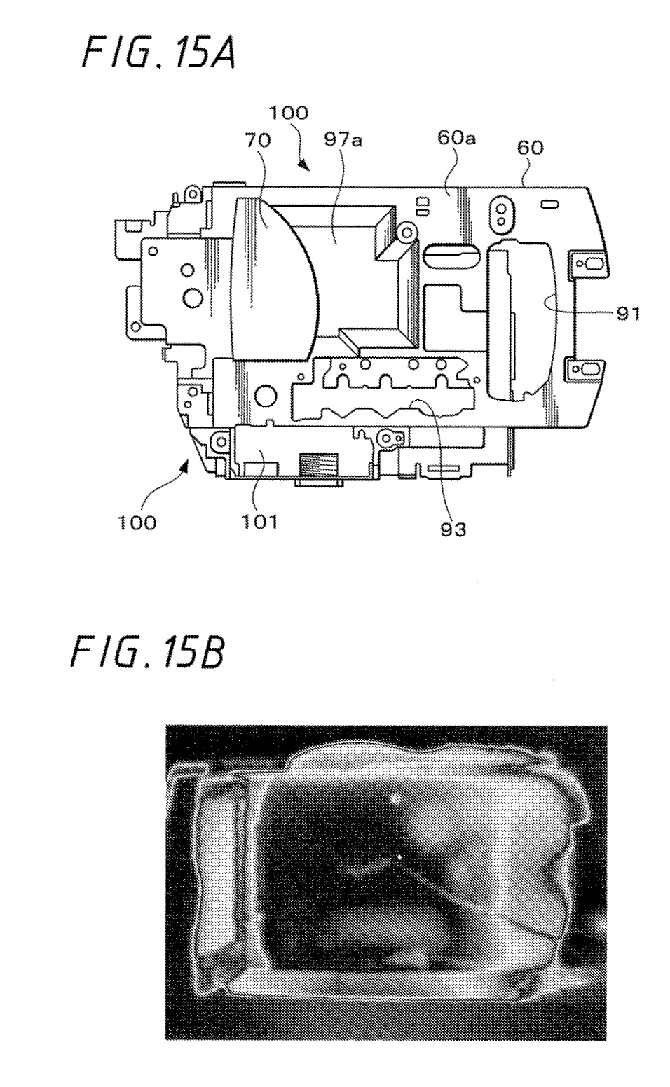

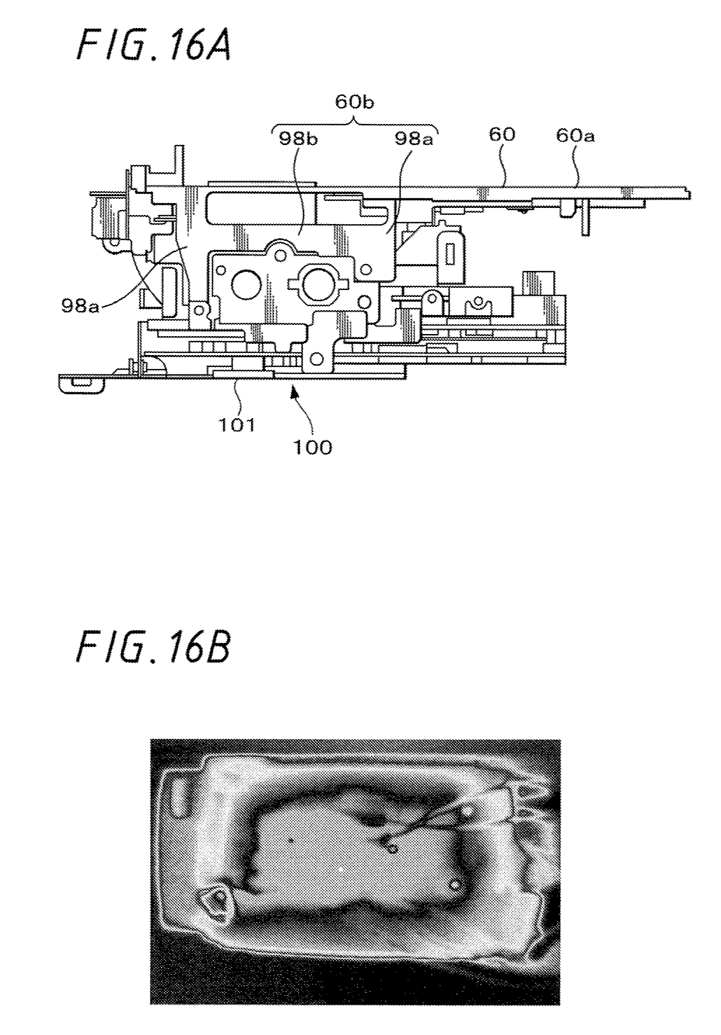

FIGS. 1 to 16 show examples of embodiments. Specifically, FIGS. 1 to 3 are a front appearance perspective view, a rear appearance perspective view, and a side view, respectively, of a digital camcorder showing a first example of electronic equipment having an enclosure according to an embodiment. FIGS. 4 to 6 are an external view, an external perspective view, and an internal perspective view, respectively, showing an enclosure according to an embodiment. FIGS. 7 to 9 are an external exploded perspective view of a metal plate layer and a resin plate layer, an internal perspective view of a resin plate layer, and an internal perspective view of a metal plate layer, respectively, also showing an enclosure according to an embodiment. FIGS. 10A and 10B are views describing an operation button connection body. FIG. 11 is an X-X line cross-sectional view of FIG. 3. FIG. 12 is a Y-Y line cross-sectional view of FIG. 4. FIG. 13 is a Z-Z line cross-sectional view of FIG. 4. FIG. 14 is a view describing a relation between an enclosure and an electronic equipment main body. FIG. 15A is a side view of an electronic equipment main body and a metal plate layer and FIG. 15B is a view describing thermal distribution in FIG. 15A. FIG. 16A is a bottom view of an electronic equipment main body and a metal plate layer and FIG. 16B is a view describing thermal distribution in FIG. 16B.

### EXAMPLE 1

First, an imaging device as a first example of electronic equipment having an enclosure according to an embodiment will be described with reference to FIGS. 1 to 3. The device shown in FIGS. 1 to 3 is a digital camcorder 1 used as a first example of an imaging device. The digital camcorder 1 includes, as an information storage medium, an optical disc that is a specific example of an information recording medium, and converts an optical image into electric signals using an imaging element (such as a CCD (charge coupled device) or a CMOS image sensor) as a specific example of an imaging mechanism, so that the image information may be recorded in the optical disc and displayed in a display device formed by a flat panel such as a liquid crystal display.

However, an information storage medium used in an imaging device as a specific example of electronic equipment according to an embodiment is not limited to optical discs (such as DVD-Rs, DVD-RWs, and DVD-RAMs) shown in this example, and it may be possible to use disc-shaped recording media such as recordable magneto-optical discs and magnetic discs including MOs and FDs. Electronic equipment using such a disc-shaped recording medium may be realized as a magneto-optical disc still camera when using a magneto-optical disc; or a magnetic disc electronic organizer when using a magnetic disc, for example.

Information storage media that may be used in an embodiment are not limited to the aforementioned disc-shaped recording media, and may be various recording media such as tape-shaped recording media using a magnetic tape, semiconductor recording media using a semiconductor memory, and card-shaped recording media using a memory card.

As shown in FIGS. 1 to 3, the digital camcorder 1 has an exterior case 2 as a specific example of an enclosure forming appearance; a disc drive device that is enclosed in the exterior case 2 and rotationally drives an optical disc detachably mounted in the disc drive device to record (write) and reproduce (read) information signals; a control circuit to control driving of the disc drive device; a lens device 3 to incorporate an object image as light and guide the image to the imaging device; and a display device 4 rotatably attached to the exterior case 2.

The exterior case 2 is formed by an approximately rectangular parallelepiped hollow enclosure and has a driving device side panel 41 and a display device side panel 42 placed opposite to each other in a transverse direction; a front panel 43 to close a front opening of a cylinder formed by combining the panels 41 and 42; and a rear panel 44 to close a rear opening of the cylinder, as shown in FIG. 11. The exterior case 2 has a longitudinal direction set to be a back-and-forth direction and is used as raised in a crosswise direction. The lens device 3 is provided in an upper part of the exterior case 2 in a state where an objective lens 5 as an imaging lens of a lens system is exposed on a front surface.

The lens device 3 is attached to the exterior case 2 in a state where an optical axis of the lens system is in a horizontal direction. The imaging element is attached to a rear part of the lens device 3 in the exterior case 2. A view finder device 6 is placed behind the lens device 3 to reflect an object image input from the lens device 3. An opening is provided in the upper part of the external case 2 to expose an accessory shoe having accessories such as a video light and an external microphone detachably mounted. The accessory shoe is placed immediately in front of the view finder device 6 and usually detachably covered with a shoe cap 7 to open and close the opening. Further, a light emitting part 8 of a flash device and an incorporated stereo-type microphone 9 are placed on a front surface of the exterior case 2.

The display device 4 is attached to a display device side panel 21B forming one side surface of the exterior case 2 so that an attitude of the display device 4 may be modified. The display device 4 has: a flat panel 10 formed by a flat liquid crystal display or the like; a panel case 11 to enclose the flat panel 10; and a panel support 12 to support the panel case 11 the attitude of which may be modified with respect to the exterior case 2. The panel support 12 has a horizontal rotation part to make the panel case 11 rotatable at approximately 90° in a horizontal direction with a vertical axis as a rotation center; and a back-and-forth rotation part to make the panel case 11 rotatable at approximately 180° in a back-and-forth direction with a horizontal axis as a rotation center.

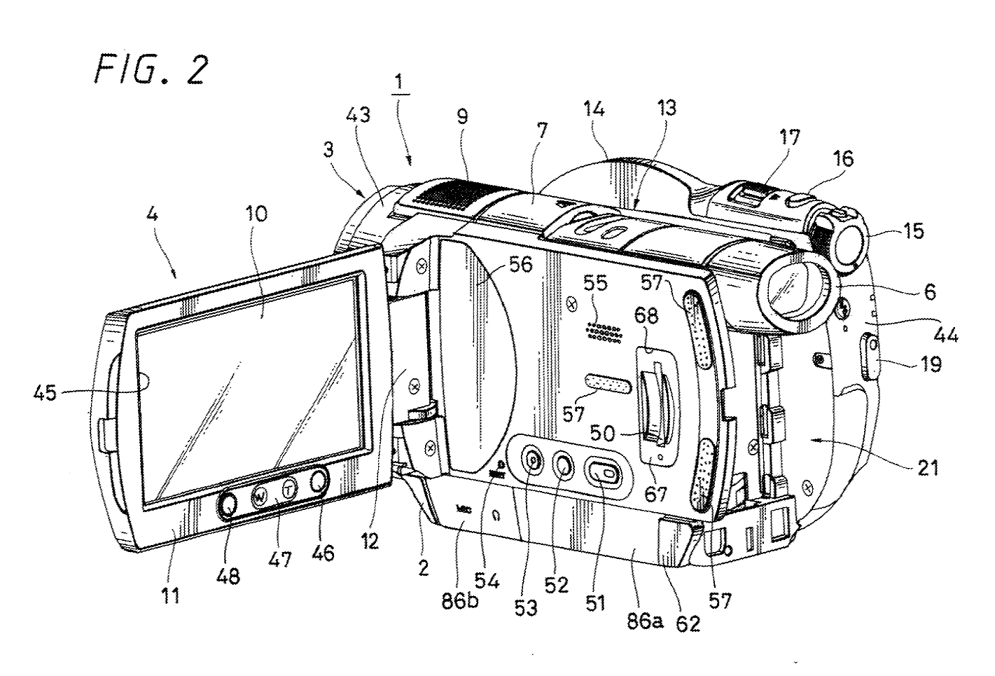

Accordingly, the display device 4 may optionally take one of the following attitudes: an attitude where the flat panel 10 is enclosed in a side surface of the exterior case 2 as shown in FIG. 1; an attitude where the flat panel 10 faces backward by rotating the panel case 11 at 90° from that state as shown in FIG. 2; an attitude where the flat panel faces forward by rotating the panel case 11 at 180° from the backward facing state; or an attitude where the flat panel 10 is in an intermediate position of these attitudes. An operation part 13 formed by a plurality of operation buttons is provided on an upper surface of the exterior case 2 above the display device 4.

A disc cover 14 to closably cover a disc mounting part having the optical disc detachably mounted is closably provided on the driving device side panel 41 forming a side surface of the exterior case 2 opposite to the display device 4. A disc drive device rotationally drives the optical disc mounted on a turntable at a predetermined velocity (for example, at a constant linear velocity) and moves an optical pickup device in a radial direction of the optical disc to record (write) and/or reproduce (read) information signals on an information recording surface of the optical disc. The disc cover 14 to cover the disc drive device has: a power source switch 15 also used as a mode selector switch; a shutter button 16 to photograph a static image; a zoom button 17 to continuously enlarge (tele) or reduce (wide) an image within a predetermined range; an opening/closing switch 18 to lock and unlock the disc cover 14; and a video recording button 19 to photograph a moving image.

The power source switch 15 has functions to switch the power source on and off by a rotation operation and to switch a plurality of function modes to each other to repeat them by performing a rotation operation with the power source switched on. Further, a hand belt (not shown) is attached to the disc cover 14 and a hand pad is mounted in the hand belt. The hand belt and the hand pad support a hand of a user holding the exterior case 2 to prevent dropping of the digital camcorder 1, for example.

The rear panel 44 forming a rear surface of the exterior case 2 has a battery housing part 21 having a battery device (not shown) as a portable power source detachably mounted. The battery housing part 21 is placed in an approximate center of the rear surface of the exterior case 2, and is provided to open backward in the rear panel 44 forming the rear surface of the exterior case 2. The video recording button 19 is placed to the right of the battery housing part 21 of the rear panel 44.

As shown in FIGS. 2 to 4, the display device 4 is placed outside the driving device side panel 41. The panel support 12 is provided in front of the panel case 11 of the display device 4. The panel case 11 is formed rotatably in a horizontal direction and a vertical direction with the panel support 12 as a rotation center. A horizontally rectangular opening window 45 is provided on an inner surface of the panel case 11, and the flat panel 10 is embedded in the opening window 45. A menu switch button 46, a zoom button 47, and a start/stop button 48 are provided on a lower side of the inner surface of the panel case 11.

The driving device side panel 41 has: a storage medium insertion opening 50 having an external memory (not shown) detachably mounted; four operation buttons 51 to 54; numerous minute through-holes 55 for a speaker device; a scratch resistant sheet 56 to protect the flat panel 10; and a cushioning material 57 for the panel case 11. The storage medium insertion opening 50 is formed as a slit hole with a size corresponding to a size of the information storage medium used, with its longitudinal direction extending in a vertical direction. The storage medium insertion opening 50 is placed in a position in the driving device side panel 41 opposite to the panel support 12 and inside the opening window 45 of the panel case 11.

The first operation button 51 is a reproduction button, the second operation button 52 is a battery power check button, the third operation button 53 is a menu simple operation button, and the fourth operation button 54 is a reset button. The four operation buttons 51 to 54 are placed in horizontal positions on a lower side of the driving device side panel 41 and inside the opening window 45 of the panel case 11. The numerous minute through-holes 55 are provided in positions obliquely above the storage medium insertion opening 50 and similarly inside the opening window 45 of the panel case 11. The speaker device (not shown) is placed inside the through-holes 55.

The scratch resistant sheet 56 prevents a metal plate layer of the driving device side panel 41 from appearing as an appearance surface to protect the flat panel 10. Accordingly, the scratch resistant sheet 56 partially overlaps a frame provided outside the opening window 45 of the panel case 11, in particular, a longitudinal frame part of the frame on a panel support 12 side. A material for the scratch resistant sheet 56 is suitably polycarbonate (PC) or polypropylene (PP), for example. Two cushioning materials 57, 57 are placed opposite to the scratch resistant sheet 56 on the driving device side panel 41. The two cushioning materials 57 are placed with an appropriate vertical interval between them and in positions overlapping the longitudinal frame part of the panel case 11.

The driving device side panel 41 forms a hybrid enclosure having a surface formed by a plastic resin plate layer and an inside formed by a metal plate layer made of a magnesium alloy or the like; that is, the hybrid enclosure is formed as a two-layer structure of the resin plate layer and the metal plate layer. The hybrid enclosure formed in this manner is as inexpensive as an enclosure formed of plastic but may be used as a frame having high strength, and may be manufactured extremely inexpensively as compared with a case where a surface is directly formed by die casting. Moreover, electronic components such as a switch and small mechanical components may directly be attached to the hybrid enclosure; accordingly, an internal frame structure and the like may be simplified. Further, when the scratch resistant sheet 56 or the like is attached to a surface of the hybrid enclosure, a contact temperature of a user may be reduced and heat radiation efficiency may be increased.

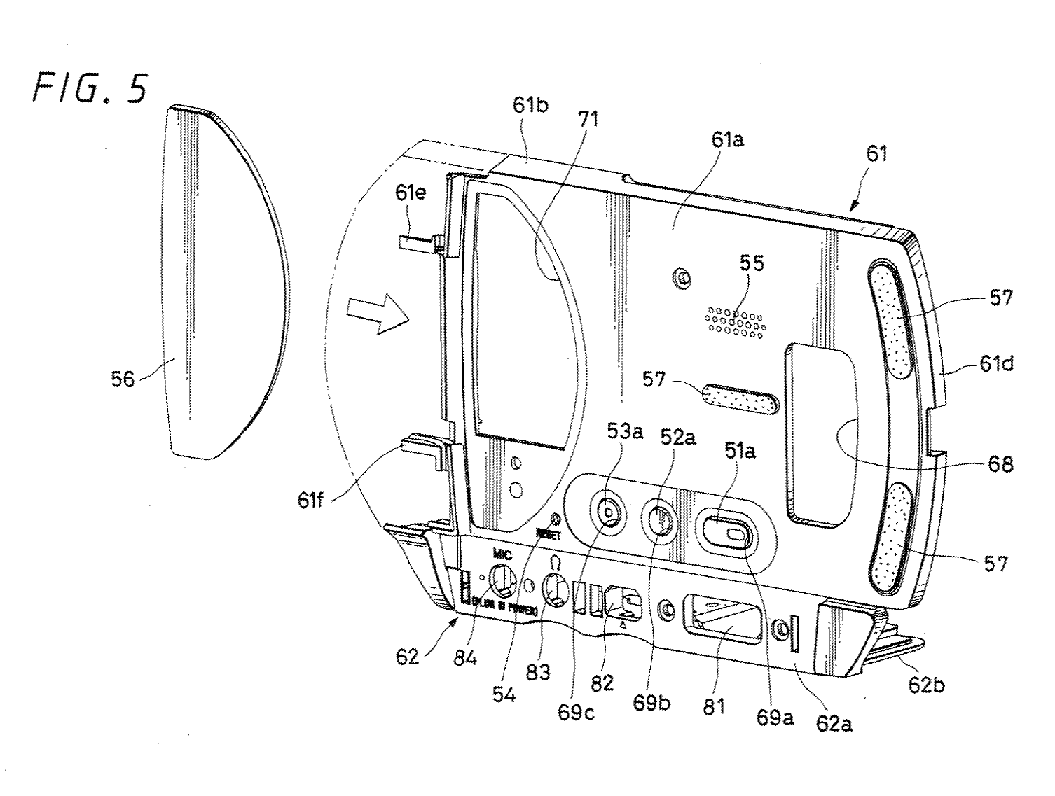

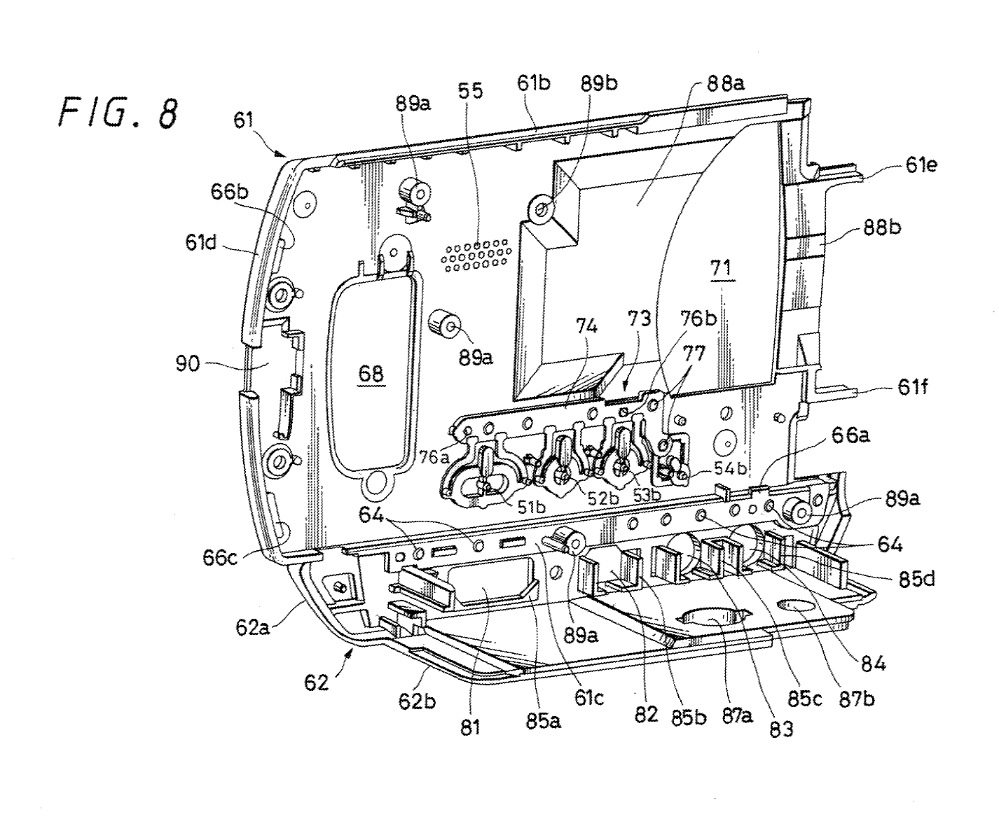

As shown in FIGS. 5 to 9, the driving device side panel 41 in this example is formed by combining one metal plate layer 60 and two resin plate layers 61 and 62 formed of separate members. The first resin plate layer 61 is vertically connected to the second resin plate layer 62. Most part of a side surface of the driving device side panel 41 corresponds to the first resin plate layer 61. The second resin plate layer 62 extends a lower part of the side surface and a lower surface continuous with a lower edge of the side surface and bent at 90° with respect to the lower edge. The two resin plate layers 61 and 62 are integrally formed when caulking parts 64 are caulked, where the caulking parts 64 are provided in a plurality of places in a part with the resin plate layers 61 and 62 overlapping each other (see FIG. 8).

As shown in FIGS. 5 to 8, the first resin plate layer 61 has a flat surface 61a forming a side surface; an upper surface 61b and a lower surface 61c continuous with upper and lower edges of the flat surface 61a; and a side surface 61d continuous with the flat surface 61a and opposite to the panel support 12. Engaging parts 61e and 61f engaged with a pair of bearings 65a and 65b of the metal plate layer 60 are provided on a panel support 12 side of the flat surface 61a. The upper surface 61b, the lower surface 61c, and the side surface 61d protrude toward a rear surface side, respectively. A first engaging pawl 66a is provided on the lower surface 61c, and a second engaging pawl 66b and a third engaging pawl 66c are provided on the side surface 61d. The three engaging pawls 66a to 66c protrude inward, respectively, and are engaged with the metal plate layer 60 to hold the metal plate layer 60 without dropping.

The first resin plate layer 61 has a fitting hole 68 in which a storage medium housing holder 67 with the storage medium insertion opening 50 is fitted; four button holes 69a, 69b, 69c, and 69d in which the four operation buttons 51 to 54 are fitted; a heat radiation fitting hole 71 in which a heat radiation part 70 of the metal plate layer 60 is fitted; and the numerous through-holes 55, each of which penetrate between a front surface and a rear surface of the first resin plate layer 61. The plurality of caulking parts 64 are provided on the lower surface 61c. An upper part of a flat surface 62a of the second resin plate layer 62 is allowed to overlap and caulked to the lower surface 61c.

The reproduction button 51 is fitted in the first button hole 69a, and the battery power check button 52 is fitted in the first button hole 69b. The menu simple operation button 53 is fitted in the third button hole 69c, and the reset button 54 is placed in the fourth button hole 69d. As shown in FIGS. 10A and 10B, operation parts 51a, 52a, 53a, and 54a of the four operation buttons 51 to 54 are integrally formed as a formed button part 73 using a resin material.

The formed button part 73 has the four operation parts 51a to 54a; a base 74 to support the four operation parts 51a to 54a in predetermined positions with predetermined intervals; and arms 74a, 74b, 74c, and 74d to connect the base 74 to the operation parts 51a to 54a. Each of the arms 74a, 74b, 74c, and 74d has a pair of arms to support each of the operation parts 51a to 54a from both sides. The arms 74a to 74d each have elasticity, so that each of the operation parts 51a to 54a may be elastically moved in a back-and-forth direction. Operation protrusions 51b, 52b, 53b, and 54b protruding to a rear surface are provided in approximate centers of the operation parts 51a, 52a, 53a, and 54a, respectively.

The base 74 of the formed button part 73 has a plurality of insertion holes 75 to attach the formed button part 73 to the first resin plate layer 61; and two positioning holes 76a and 76b to position the formed button part 73 in a predetermined position. The formed button part 73 is fixed to the first resin plate layer 61 by inserting into the insertion holes 75 a plurality of caulking protrusions 77 provided in predetermined positions on an inner surface of the flat surface 62a, respectively, and then caulking the caulking protrusions 77.

The second resin plate layer 62 has the flat surface 62a coplanar with the flat surface 61a of the first resin plate layer 61; and a bottom surface 62b continuous with a lower part of the flat surface 62a and protruding to a rear surface of the second resin plate layer 62. The flat surface 62a of the second resin plate layer 62 has a first output terminal hole 81 with an HDMI output terminal inside the hole; a second output terminal hole 82 with a component output terminal inside the hole; an earphone hole 83 with an earphone connection jack inside the hole; and a microphone hole 84 with a microphone connection jack inside the hole. As shown in FIGS. 1 to 4, the two output terminal holes 81 and 82 may be opened and closed by a first cap 86a detachably attached to the flat surface 62a. The holes 83 and 84 may also be opened and closed by a second cap 86b detachably attached to the flat surface 62a.

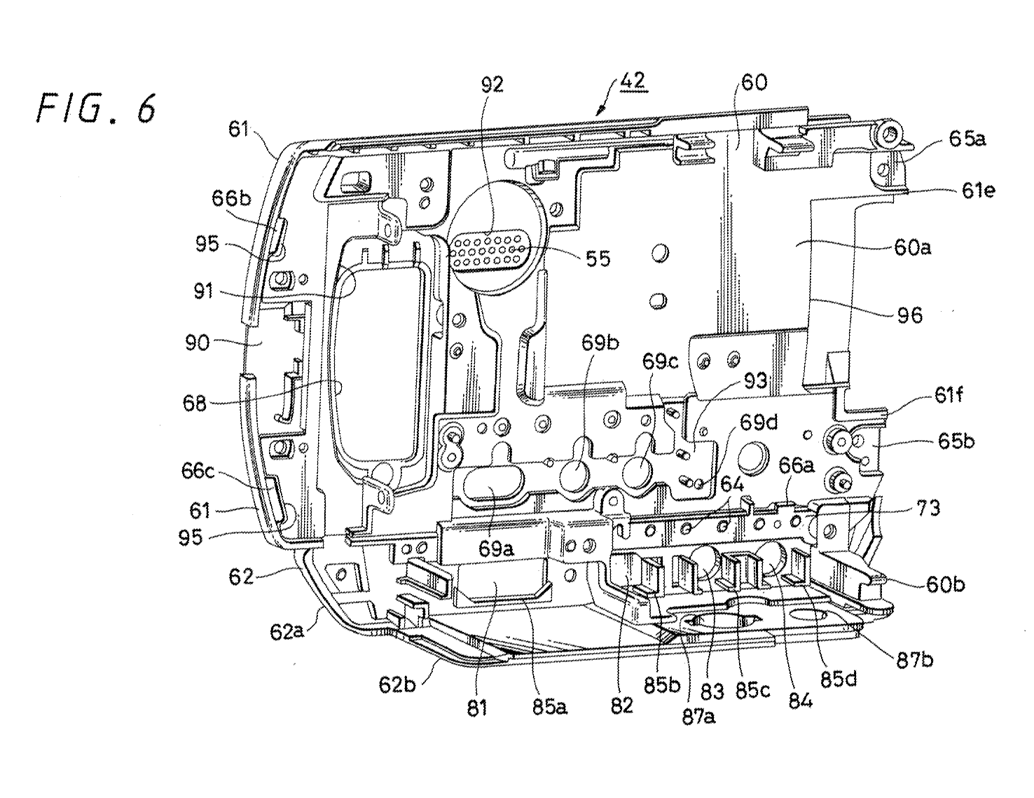

As shown in FIGS. 6 and 8, holding parts 85a, 85b, 85c, and 85d to hold output terminals and connection jacks, respectively, are provided on peripheries of the two output terminal holes 81 and 82 and the two holes 83 and 84 on the inner surface of the flat surface 62a. The bottom surface 62b of the second resin plate layer 62 has a fitting hole 87a in which a tripod nut is fitted; and a positioning hole 87b to position the nut.

The flat surface 61a of the first resin plate layer 61 has, on its inner surface, a thin part 88a having a part thinner than other parts and a thick part 88b having a part thicker than other parts. The thin part 88a is used for housing a thick part described later of the metal plate layer 60. The thin part 88a is provided in the first resin plate layer 61, making it possible to increase a thickness in a corresponding part of the metal plate layer 60 and to make a total thickness of the thin part 88a and the corresponding part equal to a thickness of other parts. The thick part 88b has an increased thickness for reinforcement.

Further, the flat surface 61a has, on its inner surface, a plurality of screwing projections 89a to screw the metal plate layer 60 to the resin plate layers 61 and 62; and a plurality of insertion holes 89b into which screw shafts are inserted. A lock pawl housing part 90 shown in FIGS. 6 and 8 encloses a lock pawl to hold the panel case 11 of the display device 4 in a housing position. The lock pawl is enclosed in the lock pawl housing part 90 and thus protrudes to an outer surface of the flat surface 61a. The display device 4 is locked in the housing position when the pawl is engaged with a tip of the panel case 11.

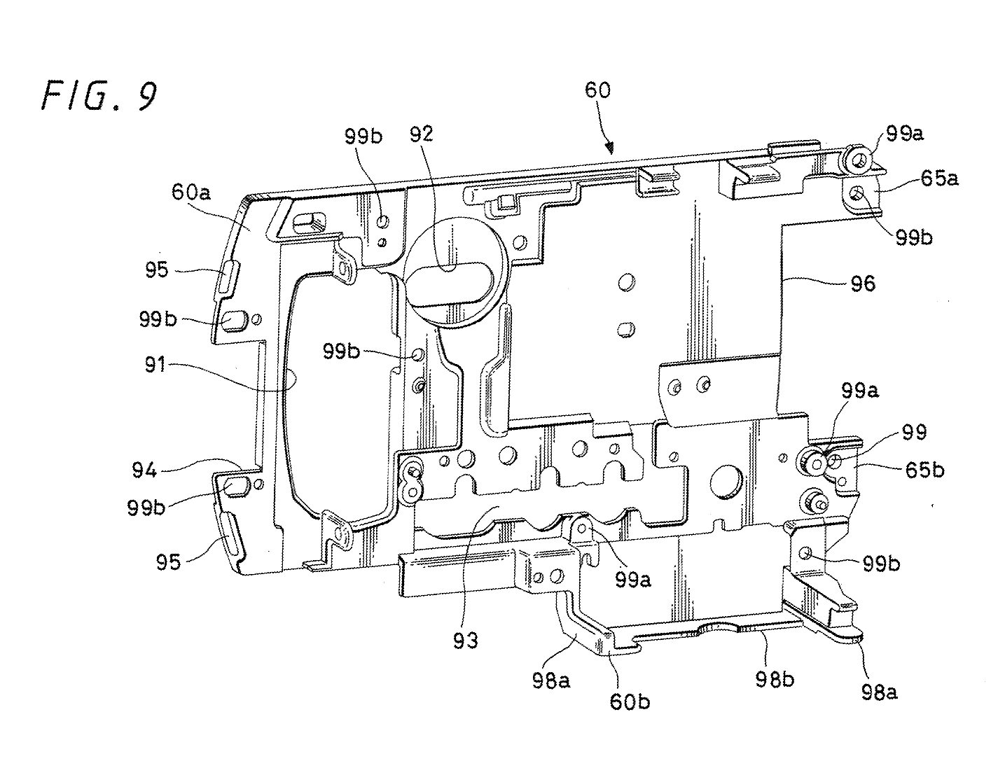

The metal plate layer 60 is a framework integrally assembled inside the resin plate layers 61 and 62. The metal plate layer 60 and the resin plate layers 61 and 62 form the display device side panel 42 forming part of an exterior case enclosure. As shown in FIG. 9, the metal plate layer 60 has a plane surface 60a placed inside the first resin plate layer 61; and a support 60b integrally formed with the flat surface 60a and protruding inside the second resin plate layer 62 to be brought into contact with the bottom surface 62b.

The flat surface 60a of the metal plate layer 60 has an external shape corresponding to a space surrounded by the upper surface 61b, the lower surface 61c, and the side surface 61d of the first resin plate layer 61 so that the metal plate layer 60 may be enclosed in the space. The flat surface 60a has a fitting hole 91 through which the storage medium housing holder 67 penetrates; a vent 92 communicating with the through-holes 55 of the first resin plate layer 61; and a formed button part hole 93 to expose a rear surface of the formed button part 73 attached to the first resin plate layer 61. The fitting hole 91 is formed slightly larger than the fitting hole 68. The vent 92 has a shape similar to the numerous assembled through-holes 55 which is a horizontal elliptical shape in this example. The formed button part hole 93 has a shape corresponding to the four continuous operation parts 51a to 54a of the formed button part 73.

Further, a first notch 94 for housing a lock pawl mechanism (not shown) is provided in a position on the flat surface 60a of the metal plate layer 60 corresponding to the lock pawl housing part 90 of the first resin plate layer 61. Two pawl receivers 95 are formed above and below the first notch 94 by recesses detachably engaged with the second and third engaging pawls 66b and 66c provided on the side surface 61d of the first resin plate layer 61. A second notch 96 engaged with the thick part 88b of the first resin plate layer 61 is provided opposite to the first notch 94 of the flat surface 60a. A thick part 97a thicker than other parts is provided in a part of the flat surface 60a continuous with inside the second notch 96. The heat radiation part 70 is provided on a second notch 96 side of the thick part 97a to protrude toward an outer surface.

The support 60b of the metal plate layer 60 has two L-letter shaped legs 98a, 98a continuous with a lower edge of the flat surface 60a and provided with a predetermined clearance in a transverse direction between them; and a base 98b to connect the two legs 98a, 98a to each other. The second output terminal hole 82, the earphone hole 83, and the microphone hole 84 are placed in a space surrounded by the two legs 98a, 98a and the base 98b. The base 98b is brought into contact with the support 62b of the second resin plate layer 62. A necessary number of screwing projections 99a and insertion holes 99b are provided in appropriate positions in the metal plate layer 60. The screwing projections 99a and the insertion holes 99b are used for fastening the metal plate layer 60 to the resin plate layers 61 and 62, fixing an electronic equipment main body 100 described later, and attaching electronic components, mechanical components, and the like which may be necessary for the electronic equipment main body 100 and other devices, for example.

The metal plate layer 60 having such a configuration is opposed to a resin plate layer assembly 59 as shown in FIG. 7. The two pawl receivers 95, 95 provided in the metal plate layer 60 are engaged with the two engaging pawls 66b and 66c provided in the first resin plate layer 61. The metal plate layer 60 is pressed to overcome the first engaging pawl 66a provided in the first resin plate layer 61, while inserting the engaging pawls 66b and 66c. Accordingly, the flat surface 60a of the metal plate layer 60 is adhered to the flat surface 61a of the first resin plate layer 61, and the support 60b of the metal plate layer 60 is adhered to the bottom surface 62b provided in the second resin plate layer 62. As a result, the metal plate layer 60 and the resin plate layer assembly 59 are adhered to each other and integrally combined as shown in FIGS. 6, 12, and 13. The formed button part 73 is attached to the first resin plate layer 61 prior to combining the metal plate layer 60 with the resin plate layer assembly 59.

In this case, the heat radiation part 70 of the metal plate layer 60 is fitted in the heat radiation fitting hole 71 of the first resin plate layer 61. The fitting hole 91 of the metal plate layer 60 is opposed to the fitting hole 68 of the first resin plate layer 61, and the vent 92 is opposed to the through-holes 55 and the four button holes 69a to 69d. Further, the thick part 97a of the metal plate layer 60 is fitted in the thin part 88a of the first resin plate layer 61, and the thick part 88b of the first resin plate layer 61 is fitted in the second notch 96.

A material for the metal plate layer 60 is preferably a magnesium alloy, for example. However, it is obviously possible to use other metals such as an aluminum alloy, a copper alloy, stainless steel, and steel. A material for the resin plate layers 61 and 62 is preferably a plastic material such as ABS (acrylonitrile-styrene-butadiene resin) or a mixed material of PC (polycarbonate) and ABS, for example. However, it is obviously possible to use other engineering plastic materials for the resin plate layers 61 and 62.

As shown in FIGS. 11 to 14, a camera main body 100 as a specific example of an electronic equipment main body is attached as held between the display device side panel 42 and the driving device side panel 41 having the aforementioned configuration. FIG. 11 shows a state where the exterior case 2 is cross-sectioned in a longitudinal direction perpendicular to an optical axis direction of the lens device 3 and the camera main body 100 is excluded. The display device side panel 42 and the driving device side panel 41 form a hollow cylinder. FIG. 14 is a schematic view showing a state where the camera main body 100 is attached to the metal plate layer 60 of the display device side panel 42 and the resin plate layer assembly 59 and the driving device side panel 41 are indicated by chain double-dashed lines.

As schematically shown, the camera main body 100 has a frame to hold the lens device 3, and a control circuit attached to the frame. The frame is formed by a base plate made of a plate material such as stainless steel mainly used for ensuring strength, and a heat conduction plate made of a plate material such as a copper plate mainly used for efficiently conducting heat. A heat conduction plate is used in the frame, because the camera main body 100 includes electronic components and devices significantly generating heat when operated.

Examples of such heat generation electronic components and devices include microcomputers, capacitors, resistors, and other electronic components used in imaging elements (such as a CCD and CMOS) or transistor circuits; and battery power supplies. In this context, the heat generation components are connected to the metal plate layer 60 through the heat conduction plate with high heat conduction efficiency, so that heat generated from the heat generation components may be immediately transferred to the metal plate layer 60. Further, heat may be actively radiated from the heat radiation part 70 of the metal plate layer 60 and other heat radiation parts of the exterior case 2.

FIGS. 12 and 13 are views describing a state where a heat conduction plate 101 of the frame is brought into contact with a circuit board 104 having an imaging element 102 and numerous electronic components 103 mounted. The imaging device 102 is mounted on one surface of the circuit board 104, and the numerous electronic components are mounted on the other surface of the circuit board 104. Part of the heat conduction plate 101 is opposed to the one surface of the circuit board 104. The heat conduction plate 101 has a swelling part 101a brought into contact with the one surface of the circuit board 104.

Part of the heat conduction plate 101 is connected to the flat surface 60a of the metal plate layer 60 through a heat radiation sheet 105, so that the heat radiation sheet 105 may actively transfer heat to the metal plate layer 60. Examples of the heat radiation sheet 105 include a silicone rubber sheet. However, a material for the heat radiation sheet is not limited to silicone rubber, and it is obviously possible to use other materials having excellent heat radiation properties.

In this case, heat transferred to the metal plate layer 60 is collected in the heat radiation part 70 through the thick part 97a. The scratch resistant sheet 56 is attached to an outer surface of the heat radiation part 70 and an operator may not directly touch the scratch resistant sheet 56. Therefore, a tactile temperature for the operator is not high, thereby preventing the operator from feeling the tactile temperature.

FIGS. 15A and 15B describe a temperature state of the camera main body 100 and FIGS. 16A and 16B describe a temperature state of the metal plate layer 60 attached to a side surface of the camera main body 100, where FIG. 15A is a side view, FIG. 15B is a photograph describing a heat generation state of FIG. 15A, FIG. 16A is a bottom view, and FIG. 16B is a photograph describing a heat generation state of FIG. 16A. White parts forming approximate quadrangles in FIGS. 15B and 16B appear yellow in color photographs, and high temperature regions (red) are within the frame parts and low temperature regions (green or blue) are outside the frame parts. According to an embodiment, almost the whole metal plate layer 60 may be uniformly heated to a high temperature, thereby increasing efficiency in heat radiation.

As described above, according to an embodiment, board-mounted components heated to high temperatures are connected to a metal having a high thermal conductivity through a heat radiation grease or heat radiation sheet to radiate heat to outdoor air. Since a metal plate layer in a heat radiation metal component may be formed with various shapes as compared with a plate component, a metal plate layer formed of a magnesium alloy or the like is often used for an enclosure. However, since a metal has a surface tactile temperature higher than in a resin plate layer, low temperature burns may occur when the metal plate layer is exposed in a place often touched by an equipment user. Therefore, such a drawback may be prevented by completely covering a metal plate layer with a resin plate layer as in an embodiment. The resin plate layer and the metal plate layer may be completely integrated by screwing the metal plate layer through the resin plate layer. Further, when a single-layer structure of the metal plate layer is formed in a part that may not have a two-layer structure due to thickness limitations and a sheet member such as a scratch resistant sheet is attached to a surface of the metal plate layer, safety may be improved without an increase in total thickness.

Portable electronic equipment is expected to be reduced in size and have improved functions. Since the electronic equipment generates an increased amount of heat due to the improved functions and has a reduced heat radiation area due to the reduction in size, the electronic equipment is expected to have a further increased internal temperature. Accordingly, a die cast product of a material having a high thermal conductivity such as a magnesium alloy is expected to be used as an equipment enclosure in order to improve a heat radiation effect. In this case, a tactile temperature may be so high that a user feels thermally unusual in electronic equipment heated to a high internal temperature. Even in such a case, according to an embodiment, a metal plate layer is externally covered with a resin plate layer, making it possible to reduce a tactile temperature of electronic equipment for a user.

Further, an electronic equipment enclosure having a metal plate layer as a framework in a resin plate layer may have stiffness considerably increased as compared with an electronic equipment enclosure having a single plastic structure. In addition, since an excessive thickness may be eliminated, electronic equipment may be reduced in size and weight. Further, electronic equipment having an appearance surface formed by a resin plate layer may be decorated, for example, painted, sputtered, printed, and marked in more various ways and may have more excellent appearance as compared with electronic equipment having a die cast appearance surface. Die cast components may not necessarily be manufactured uniformly unlike molded components and tend to have inferior appearance. A die cast component not having inferior appearance is manufactured only in a yield lower than that of a molded component not having inferior appearance, resulting in an expensive die cast component having decorated appearance. However, a die cast component having a two-layer structure of a resin plate layer and a metal plate layer according to an embodiment may be manufactured at a relatively low cost.

In order to make die cast components electrically conductive to other components, the die cast components may be necessary to have a contact surface with the other components free of resistance due to painting or the like. Therefore, it may be necessary to subject the electrically conductive surface to treatment such as masking, resulting in an increase in decoration cost. However, according to the embodiment, a resin plate layer forms an appearance surface, so that an internal metal plate layer may optionally be induced to be electrically conductive. Therefore, an internal circuit is not affected by unexpected external static electricity.

The present application is not limited to the embodiments described above and shown in the drawings, and various modifications may be effected without departing from the gist of the present application. For example, in the aforementioned example, an electronic equipment enclosure according to an embodiment is used for a digital camcorder as a specific example of an imaging device; however, the electronic equipment enclosure may be used not only for an analog camcorder, but also for various other types of electronic equipment such as an electronic still camera, an imaging device such as DSC, a personal computer, a portable telephone, a PHS, telecommunication equipment, a personal computer terminal, an electronic dictionary, a DVD player, a car navigation system, and the like. In particular, such an enclosure is suitably used for small electronic equipment having numerous types including numerous destinations and models.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. An enclosure to cover at least part of an electronic equipment main body, the enclosure comprising:
a flat metal plate layer die cast on an inner surface; and
a flat resin plate layer molded on an outer surface to almost entirely cover an outer surface of the metal plate layer, the enclosure formed to have a two-layer structure of the metal plate layer and the resin plate layer.

2. An electronic equipment enclosure according to claim 1, wherein the resin plate layer has an opening penetrating between a front surface and a rear surface of the resin plate layer to expose part of the metal plate layer from the opening, and an exterior sheet is attached to a surface of the exposed part.

3. An electronic equipment enclosure according to claim 1, wherein the resin plate layer has a resin side opening penetrating between a front surface and a rear surface of the resin plate layer; the metal plate layer has a metal side opening overlapping the resin side opening and penetrating a front surface and a rear surface of the metal plate layer, and a screw hole to expose part of a component of the electronic equipment main body through the metal side opening from the resin side opening; and the component is screwed to the metal plate layer.

4. An electronic equipment enclosure according to claim 1, wherein the metal plate layer has a screw hole to screw the electronic equipment main body or a component of the electronic equipment main body to the metal plate layer.

5. An electronic equipment enclosure according to claim 1, wherein the metal plate layer has a metal side opening penetrating between a front surface and a rear surface of the metal plate layer, and a vent in a position corresponding to the metal side opening of the resin plate layer.

6. An electronic equipment enclosure according to claim 1, wherein the metal plate layer is thicker than the resin plate layer in a part of the enclosure demanding strength, and the resin plate layer is thicker than the metal plate layer in a part of the enclosure not demanding strength.

7. An electronic equipment enclosure according to claim 1, wherein the metal plate layer is formed by magnesium die casting.

8. Electronic equipment having an electronic equipment main body at least partially covered with an enclosure, the enclosure comprising:
a flat metal plate layer die cast on an inner surface; and a flat resin plate layer molded on an outer surface to almost entirely cover an outer surface of the metal plate layer, the enclosure formed to have a two-layer structure of the metal plate layer and the resin plate layer.
